(19) United States
(12) Patent Application Publication
(10) Pub. No.: US 2011/0158845 A1
(43) Pub. Date: Jun. 30, 2011

(54) Al-Ni ALLOY WIRING ELECTRODE MATERIAL

(75) Inventors: Shigeki Tokuchi, Saitama (JP); Ryoma Tsukuda, Saitama (JP); Tomoyasu Yano, Saitama (JP); Yoshinori Matsuura, Saitama (JP); Takashi Kubota, Saitama (JP)

(73) Assignee: MITSUI MINING & SMELTING CO., LTD., Tokyo (JP)

(21) Appl. No.: 13/002,892

(22) PCT Filed: Mar. 13, 2009
(86) PCT No.: PCT/JP2009/054931

§ 371 Date: Jan. 6, 2011

(30) Foreign Application Priority Data
Jul. 7, 2008 (JP) 2008-177398
Feb. 10, 2009 (JP) 2009-028642

(51) Int. Cl. C22C 21/00; C23C 14/34

(52) U.S. Cl. 420/550; 204/298.13

(57) ABSTRACT

To provide an Al—Ni alloy wiring electrode material, which has flexibility suitable for organic EL, can be directly bonded to a transparent electrode layer of ITO or the like, and is excellent in corrosion resistance against developers. An Al—Ni alloy wiring electrode material containing aluminum, nickel and boron, wherein the material contains a total of 0.35 at % to 1.2 at % of nickel and boron with the balance being aluminum. It is also preferred that the Al—Ni alloy wiring electrode material contain 0.3 at % to 0.7 at % of nickel and 0.05 at % to 0.5 at % of boron.

### TECHNICAL FIELD

The present invention relates to an Al—Ni alloy wiring electrode material used for an element of a display device, and in particular to an Al—Ni—B alloy wiring electrode material suitable for an organic EL display.

### BACKGROUND ART

Displays employing, for example, a thin film transistor (hereinafter abbreviated as TFT) are now widely used as a display device for information equipment, AV equipment and household appliances. For such displays, various control structures have been proposed, such as liquid crystal displays (LCDs) and self-luminous organic EL displays (OELDs) based on an active matrix system, which typically uses TFTs, or organic EL displays based on a passive matrix system. These control structures are constructed from a circuit formed using a thin film.

Such display devices generally have a transparent electrode, which is typically an ITO electrode, a thin film transistor, a conductive electrode for wiring and the like. Materials used for such display devices have a direct influence on the quality of display, the power consumption and the production cost, and thus they are technically improved every day.

For the structure of such display devices, the following technical improvement is ongoing, for example, in liquid crystal displays (LCDs).

There is a remarkable progress in high definition and cost reduction of liquid crystal display devices which now dominate display devices, and structures using a TFT are now widely used as their elements. Aluminum (Al) alloys are used as a wiring material of the circuit. This is a consequence of attention to aluminum which has low specific resistance and is easily processed into wiring as an alternative material to improve extremely high specific resistance of high melting point materials which have been used so far, such as tantalum, chromium, titanium and alloys thereof.

When a thin film circuit is formed with aluminum alloy, the following phenomenon is known to occur at the contact portion with a transparent electrode such as an ITO electrode in an LCD. That is, when an Al alloy and an ITO (indium tin oxide) electrode are directly bonded, the difference in the electrochemical properties between the two causes a reaction at the bonded interface, resulting in collapse of the bonded interface or an increase in the resistance value. Therefore, when an Al alloy is used for a liquid crystal display element, a so-called contact barrier layer (or a cap layer; hereinafter the term “contact barrier layer” is used as a term including cap layers) composed of Mo or Cr is formed (see, for example, Non Patent Document 1).

In other words, generally a contact barrier layer composed of Cr, Mo or the like as main materials has been provided in a TFT having a wiring electrode of such an Al alloy. The presence of the contact barrier layer has made the structure of display devices complicated, and has caused an increase in the production cost. Also, market trends recently have a tendency to exclude the use of Cr which is one of the materials constituting the contact barrier layer, and so there is now much restriction on techniques of forming contact barrier layers.

For that reason, recently the contact barrier layer mentioned above has been omitted, and Al—Ni alloy wiring materials of a specific composition which can be directly bonded to a transparent electrode such as an ITO electrode have been proposed (see Patent Document 1 to Patent Document 3). Also, Al—Ni alloy wiring materials for the use of reflective films have been proposed (Patent Document 4).

However, most of the Al—Ni alloy wiring materials proposed in the above prior art have been developed basically for liquid crystal display (LCD) devices, and there are no substantial studies on whether or not the materials can be suitably used for self-luminous organic EL displays (OELDs).

Organic EL displays are self-luminous and thus the laminate thickness upon the formation of an element can be made extremely thin. Use of a flexible plastic plate or the like instead of a glass substrate can achieve a so-called flexible display (bendable display panel). From this point of view, flexibility is required as a physical property of materials used for organic EL displays, but no consideration is given to flexibility in the Al—Ni alloy wiring materials in the prior art documents described above.

Recent organic EL displays have employed LTPS (low-temperature polysilicon)-TFT as a drive system, and an Al—Ni alloy is used as a lead wiring material or a reflective film material in the system. However, conventional Al—Ni alloy wiring materials cannot be used for both of the lead wiring and the reflective film in organic EL displays, and therefore the two are separately treated at present. Thus, wiring electrode materials of an Al—Ni alloy applicable to both lead wiring and reflective film are needed for organic EL displays.

Further, it has been pointed out that when a circuit of an element is formed with a conventional Al—Ni alloy wiring material, the Al—Ni alloy tends to be corroded upon contact with a developer used for forming the circuit, and so the alloy is difficult to be applied to conventional manufacturing steps. Portions in contact with a developer are to be dissolved in the etching step and normally, the corrosion with the developer does not cause any problem for the formation of the circuit. However, it is a problem when there is trouble in the development step and resist is once stripped to repeat the development step, i.e., when a step called photo rework is carried out. In the case of carrying out this photo rework, the progress of the corrosion with a developer in the previous development step causes dissolution of Al—Ni alloy and thus makes the photo rework impossible. Since the photo rework step is generally employed to improve the production yield by manufacturers of display devices, i.e., panel manufacturers, Al—Ni alloy wiring materials having a certain degree of corrosion resistance against developers are in demand.

So, for the reasons described above, there has been a tendency to pursue an Al—Ni alloy wiring material which can solve the problems of difficulty of the formation of circuits caused by dissolution of Al—Ni alloy due to the corrosion with a developer, or an increase in bond resistance upon direct bonding with a transparent electrode caused by oxidation of the Al—Ni alloy surface. Accordingly, to respond to the corrosion with a developer, a technique of nitriding or oxidizing the surface of an Al alloy film has been proposed as a method of improving the corrosion resistance of Al—Ni alloy wiring materials (see Patent Document 5).

However, a disadvantage of the nitriding or oxidation of the surface of Al alloy is that the time of sputtering treatment upon the formation of thin film is prolonged. Further, since it is necessary to introduce nitrogen gas or oxygen gas into the chamber of a sputtering apparatus for the nitriding or oxidation, particles are likely to be generated upon sputtering, sometimes making it difficult to form a good Al alloy film. Moreover, when a circuit is formed by etching an Al alloy film on which a nitride film or an oxide film has been formed, since the etching rate of the nitride film or the oxide film formed on the surface of Al alloy film differs from the etching rate of portions of the Al alloy film other than the surface, etching proceeds more slowly on the surface of the Al alloy, i.e., on the nitride film or the oxide film. As a result, etching residues remain on the surface of the Al alloy film, and thus the circuit tends to have a reversely tapered cross-section. Although it is possible to take a measure to use a special etchant in order to normalize the cross-sectional shape of the circuit, the use thereof causes an increase in the production cost and thus is not preferred. For these reasons, Al—Ni alloy wiring materials excellent in corrosion resistance against developers used in forming a circuit are in demand.

### PRIOR ART DOCUMENTS

[Non Patent Document 1] “Jisedai Ekisho Disupurei Gijutsu (Next-generation Liquid Crystal Display Technology)” written and edited by Tatsuo Uchida, First edition, Kogyo Chosakai Publishing, Inc., Nov. 1, 1994, p. 36-38
[Patent Document 1] Japanese Patent Appln. Laid-Open No. 2004-214606
[Patent Document 2] Japanese Patent Appln. Laid-Open No. 2007-142356
[Patent Document 3] Japanese Patent Appln. Laid-Open No. 2006-261636
[Patent Document 4] International Publication No. WO2008/047511
[Patent Document 5] Japanese Patent Appln. Laid-Open No. Hei 11-284195

### DISCLOSURE OF THE INVENTION

### Problems to be Solved by the Invention

The present invention has been made under such circumstances and an object thereof is to provide an Al—Ni alloy wiring electrode material which is suitable for cases where materials used need to have flexibility as for organic EL and which can be directly bonded to a transparent electrode layer of ITO or the like and is excellent in corrosion resistance against a developer.

### Means for Solving the Problems

To solve the above problems, the present invention provides an Al—Ni alloy wiring electrode material containing aluminum, nickel and boron, wherein the material contains a total of 0.35 at % to 1.2 at % of nickel and boron with the balance being aluminum. Preferably, the Al—Ni alloy wiring electrode material according to the present invention contains 0.3 at % to 0.7 at % of nickel and 0.05 at % to 0.5 at % of boron.

In the Al—Ni alloy wiring electrode material according to the present invention, when the content of nickel is represented by nickel atomic percent X at % and the content of boron is represented by boron atomic percent Y at %, it is further preferred that the contents thereof be in the range of a domain satisfying the formulas 0.3≦X, 0.05≦Y≦0.5 and Y>2X−0.9.

It is preferred that the Al—Ni alloy wiring electrode material according to the present invention be used for organic EL.

The present invention also provides a sputtering target for forming a wiring electrode film composed of an Al—Ni alloy wiring electrode material, wherein the sputtering target contains a total of 0.35 at % to 1.2 at % of nickel and boron with the balance being aluminum.

### Advantageous Effects of the Invention

The present invention can provide an Al—Ni alloy wiring electrode material which can be directly bonded to a transparent electrode layer of ITO or the like, is excellent in corrosion resistance against developers, and is suitable for cases where materials used need to have flexibility as in organic EL. The Al—Ni alloy wiring electrode material of the present invention is also suitable for a lead wiring material and a reflective film material in organic EL.

### BRIEF DESCRIPTION OF THE DRAWINGS

FIG. 1 is a schematic perspective view of a test sample in which an ITO electrode layer and an Al alloy electrode layer are stacked crosswise.

FIG. 2 is a plotted graph of the data of samples in Table 1.

### MODE FOR CARRYING OUT THE INVENTION

In the following, embodiments of the present invention is described. The Al alloy wiring material according to the present invention is suitable as a wiring material for display devices such as information equipment, AV equipment and household appliances, and is particularly suitable for forming display devices with organic EL. However, the present invention is applicable to a wiring material for not only active matrix type liquid crystal displays or organic EL type displays, but also various types of display devices.

The Al—Ni alloy wiring electrode material according to the present invention contains aluminum, nickel and boron, and the material contains a total of 0.35 at % to 1.2 at % of nickel and boron, and the balance is aluminum. When nickel and boron are added to aluminum in a total content of 0.35 at % to 1.2 at %, the resulting Al—Ni alloy wiring electrode material has excellent corrosion resistance against a developer, has corrosion resistance close to pure Al and itself is flexible compared to conventional Al—Ni alloy wiring materials. The flexibility of the wiring electrode material itself is evaluated based on the hardness of Al—Ni alloy itself. When the total content is less than 0.35 at %, the wiring material has a Vickers hardness of less than Hv 25, and the wiring material itself is too soft and easily scratched. On the other hand, when the total content is more than 1.2 at %, the wiring material has a Vickers hardness of more than Hv 40 and becomes hard, and it is more likely that the material becomes difficult to use for flexible substrates or the like. The Al—Ni—B alloy wiring material according to the present invention may contain, for example, gas components or other unavoidable impurities which may be mixed thereinto in the step of preparing the material, the step of forming a wiring circuit, the step of producing an element, or the like, to the extent that the advantageous effects of the present invention described below are kept.

The Al—Ni alloy wiring electrode material according to the present invention is different from the materials of the above-described prior arts (Patent Document 1 to Patent Document 4) in that the material has corrosion resistance against an alkaline developer containing tetramethylammonium hydroxide used in the development step. This means that a photo rework step can be employed. Further, the Al—Ni alloy wiring electrode material according to the present invention is characterized in that the material itself has flexibility. The material is suitable for cases where materials used need to have flexibility as for organic EL.

Nickel forms an intermetallic compound with aluminum by heat treatment and has an improving action on bonding properties upon direct bonding to a transparent electrode layer. However, a higher nickel content tends to increase the specific resistance of wiring circuit, and thus the corrosion resistance against developers is reduced. Also, a lower nickel content causes a decrease in the amount of generation of an intermetallic compound with aluminum and makes direct bonding to a transparent electrode layer impossible, and also may result in a decrease in heat resistance (action to suppress the occurrence of plastic deformation of Al—Ni alloy wiring electrode materials due to heat). For this reason, the content of nickel is preferably 0.3 at % to 0.7 at %.

When the content of nickel is more than 0.7 at %, the specific resistance value after a heat treatment at 300° C. tends to increase. Also, when the content of nickel is less than 0.3 at %, defective dents called dimples are likely to be formed and the heat resistance may not be maintained, and also the bond resistance value upon direct bonding to a transparent electrode of ITO or the like tends to be increased. The dimple means a defect of a very small dent formed on the surface of an Al—Ni alloy wiring electrode material due to stress strain generated when the material is heat treated. The generation of dimples has a negative impact on the bonding properties to reduce bonding reliability. On the other hand, a so-called hillock is a projection formed on the surface of an Al—Ni alloy wiring electrode material due to stress strain generated when the material is heat treated. The generation of hillocks also has a negative impact on the bonding properties to reduce bonding reliability. The dimples and hillocks are both plastic deformation of Al—Ni alloy caused by heat, and the phenomena are collectively called stress migration. The level of the occurrence of these defects helps to determine the heat resistance of Al—Ni alloy wiring electrode materials.

The Al—Ni alloy wiring electrode material according to the present invention contains a predetermined amount of boron in addition to nickel. The addition of boron makes it possible to prevent mutual diffusion of Al and Si at the bonding interface upon direct bonding to a semiconductor layer of n⁺-Si or the like. Boron acts on the heat resistance as nickel does, and when boron is included, precipitates of intermetallic compounds generated upon heat treatment tend to be small. The content of boron is preferably 0.05 at % to 0.5 at %. When the content of boron is more than 0.5 at %, the specific resistance value after heat treatment at 300° C. tends to increase. On the other hand, when the content of boron is less than 0.05 at %, the heat resistance in heat treatment at 300° C. cannot be ensured.

In the Al—Ni alloy wiring electrode material according to the present invention, when the content of nickel is represented by nickel atomic percent X at % and the content of boron is represented by boron atomic percent Y at %, it is further preferred that the contents thereof be in the range of a domain satisfying the formulas 0.3≦X, 0.05≦Y≦0.5 and Y>2X−0.9. This is because in the above composition range, the resulting Al—Ni alloy wiring electrode material has very good overall properties including a specific resistance value of 3.6 μΩcm or less, a hardness of 40 Hv or less, excellent corrosion resistance, good bonding properties to a transparent electrode of ITO or the like, and good heat resistance in heat treatment at 300° C.

When an element is formed, a metal film composed of Mo or Mo alloy, Ti or Ti alloy, or Cr or Cr alloy, or a transparent electrode material film containing In₂O₃, SnO₂ or ZnO used for a transparent electrode material such as ITO, IZO or ZnO may be stacked on any one of the upper layer and the lower layer or on both sides of a thin film of the Al—Ni alloy wiring electrode material according to the present invention. Although the structure of elements of display devices includes various bonding patterns such as direct bonding of a wiring material itself to a transparent electrode material such as ITO and bonding via a metal layer of Mo or the like, the Al—Ni alloy wiring electrode material according to the present invention allows a metal film of Mo or Mo alloy, Ti or Ti alloy, or Cr or Cr alloy, or a transparent electrode material film containing In₂O₃, SnO₂ or ZnO used for a transparent electrode material such as ITO, IZO or ZnO to be stacked.

When an element of a display is produced using the above Al—Ni alloy wiring electrode material according to the present invention, a sputtering target composed of a total of 0.35 at % to 1.2 at % of nickel and boron with aluminum being the balance is preferably used. When a sputtering target of such a composition is used, an Al—Ni—B alloy thin film having substantially the same composition as the target composition can be easily formed although it is somewhat dependent on the film forming conditions in sputtering.

Practically, it is desirable that the Al—Ni alloy wiring electrode material according to the present invention be formed into a film by a sputtering method as described above, but different methods may also be adopted. For example, dry methods such as vapor-deposition techniques and spray forming methods may be employed, or a wiring circuit may be formed by an aerosol deposition method using alloy particles having the composition of the Al—Ni alloy of the present invention as a wiring material, or a wiring circuit may be formed by an ink-jet method.

### EXAMPLES

Next, the Al—Ni alloy wiring electrode material according to the present invention is described in detail with reference to Examples.

In the present Examples, material properties of Al—Ni—B alloys having the respective compositions shown in Table 1 were evaluated. First, sputtering targets having different Ni and B contents were prepared as shown with the respective sample numbers in Table 1. The sputtering targets were prepared by mixing the respective metals so as to achieve their contents of the compositions, melting and stirring the same in vacuum, casting it in inert gas atmosphere, then rolling and molding the resulting ingot, and flattening the surface to be subjected to sputtering.

Then Al—Ni—B alloy thin films were formed using the sputtering targets having the compositions of the respective sample numbers, and the film properties and the element properties were evaluated. The properties of the specific resistance, hardness, corrosion resistance against developers, heat resistance and ITO bond resistance of the films were evaluated.

The conditions of the evaluation of the properties are described below.

Specific resistance: A single film (thickness: 2800 Å) was formed on a glass substrate by sputtering and heat treated in vacuum (1×10⁻³ Pa) at 320° C. for 30 minutes, and then the specific resistance values of the films of the respective compositions were measured by a 4-terminal resistance measurement apparatus (B-1500A made by Agilent Technologies Inc.). For the sputtering conditions, a magnetron sputtering apparatus was used with an input electric power of 3.0 W/cm² at an argon gas flow rate of 100 sccm and an argon pressure of 0.5 Pa.

Hardness: Since hardness values vary due to the influence of substrates or a difference in the measurement apparatus when an attempt is made to measure the hardness of a thin film, the hardness of the films of the respective compositions was determined by measuring the hardness of the target materials for forming the films of the respective compositions instead. More specifically, a 10 mm×10 mm×10 mm bulk body was cut from the target materials for forming the films of the respective compositions, and after the surface to be measured was polished, the hardness was measured at 10 points by Vickers Hardness Tester (made by Matsuzawa Seiki Co., Ltd.) and the average hardness value was calculated.

Corrosion resistance against developer: For the corrosion resistance against a developer of the films of the respective compositions, a single film (thickness: 2000 Å) was formed on a glass substrate under the same conditions as in the measurement of the specific resistance of the film described above, and after part of the single film was coated with a resist and exposed, the film was immersed in an alkaline developer containing tetramethylammonium hydroxide (hereinafter abbreviated as a TMAH developer) for 60 seconds to strip the resist; and then the step height was measured (by contact stylus profilometer P-15 made by KLA-Tencor Co., Ltd.) to determine the amount of dissolution by a developer (decrease in the thickness of the film). The concentration of the TMAH developer was 2.38% and the liquid temperature was 23° C. The amount of dissolution (decrease in the thickness of the film) of a single film of pure Al when the film was immersed in the TMAH developer for 60 seconds was 105 Å.

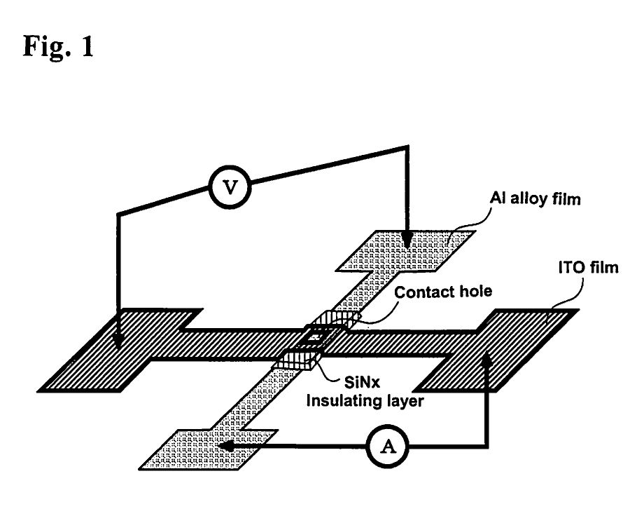

ITO bond resistance: The bond resistance value upon direct bonding to ITO was evaluated using a test sample (Kelvin element) prepared by forming an ITO (In₂O₃-10 wt % SnO₂) electrode layer (500 Å thick, circuit width: 50 μm) on a glass substrate and forming thereon an aluminum alloy film layer of each composition (2000 Å thick, circuit width: 50 μm) crosswise as shown in the schematic perspective view of FIG. 1.

For preparing the test samples, first an aluminum alloy film having a thickness of 2000 Å was formed on a glass substrate using an Al—Ni alloy target of each composition under the above-described sputtering conditions (magnetron sputtering apparatus, input electric power: 3.0 W/cm², argon gas flow rate: 100 ccm, argon pressure: 0.5 Pa). The temperature of the substrate upon sputtering was set at 100° C. Then the surface of the resulting aluminum alloy film was coated with a resist (viscosity: 15 cp, TFR-970 made by Tokyo Ohka Kogyo Co., Ltd.) and exposed after attaching thereto a pattern film for forming a 50 μm wide circuit, and the film was developed using a TMAH developer having a concentration of 2.38% at a liquid temperature of 23° C. After the development, a circuit was formed using a phosphoric acid type mixed acid etchant (available from KANTO CHEMICAL CO., INC.) and the resist was removed using an aqueous amine stripping solution (40° C., TST-AQ8 available from Tokyo Ohka Kogyo Co., Ltd.) to form a 50 μm wide aluminum alloy layer circuit.

Then the substrate on which the 50 μm wide aluminum alloy layer circuit was formed was washed with pure water and dried, and then an insulating layer of SiNx (thickness: 4200 Å) was formed on the surface. The insulating layer was formed by using a CVD apparatus (PD-2202L made by SAMCO Inc.) under CVD conditions of an input electric power RF of 250 W, a NH₃ gas flow rate of 10 ccm, a flow rate of SiH₄ gas diluted with H₂ of 100 ccm, a nitrogen gas flow rate of 200 ccm, a pressure of 80 Pa and a substrate temperature of 350° C.

Subsequently, the surface of the insulating layer was coated with a positive resist (TFR-970 available from Tokyo Ohka Kogyo Co., Ltd.) and a pattern film for opening a 10 μm×10 μm square contact hole was attached thereto to perform exposure, and the resultant was developed using a TMAH developer. Then a contact hole was formed using a dry etching gas of SF₆. The conditions of forming the contact hole included a SF₆ gas flow rate of 50 sccm, an oxygen gas flow rate of 5 sccm, a pressure of 4.0 Pa and an output of 100 W.

The resist was stripped using an aqueous amine stripping solution (40° C., TST-AQ8 available from Tokyo Ohka Kogyo Co., Ltd.). After the resist was stripped, the resultant was cleaned by immersing in an ammonium alkaline cleaning solution (a solution prepared by diluting special grade 25% aqueous ammonia available from Wako Pure Chemical Industries, Ltd. to pH 10 or less) at a liquid temperature of 25° C. for a treatment time of 60 seconds, and then washed with water and dried. A transparent electrode layer of ITO was formed in and around the contact hole of the samples from which the resist was stripped, using an ITO target (composition: In₂O₃-10 wt % SnO₂). The transparent electrode layer, i.e., an ITO film having a thickness of 1000 Å, was formed by sputtering (substrate temperature: 70° C., input electric power: 1.8 W/cm², argon gas flow rate: 80 sccm, oxygen gas flow rate: 0.7 sccm, pressure: 0.37 Pa).

The surface of the ITO film was coated with a resist (TFR-970 available from Tokyo Ohka Kogyo Co., Ltd.) and a pattern film was attached thereto to perform exposure, and the resultant was developed using a TMAH developer, and an oxalic acid type mixed acid etchant (ITO07N available from KANTO CHEMICAL CO., INC.) was used to form a 50 μm wide circuit. After the ITO film circuit was formed, the resist was removed using an aqueous amine stripping solution (40° C., TST-AQ8 available from Tokyo Ohka Kogyo Co., Ltd.).

The test samples obtained by the preparation process described above were heat treated in air atmosphere at 250° C. for 30 minutes, and the voltage when a current of 100 μA was passed through the terminal parts of the test samples shown by the arrows in FIG. 1 was measured to determine the bond resistance.

Heat resistance: For the evaluation of the heat resistance of the films of the respective compositions, a single film (thickness: about 0.3 μm) was formed on a glass substrate by sputtering (under the same conditions as in the evaluation of the specific resistance described above), and after heat treatment in vacuum (1×10⁻³ Pa) at 300° C. for 30 minutes, the film surface was observed by a scanning electron microscope (SEM, 10,000× magnification). In the SEM observation, 5 fields of an observation area of 10 μm×8 μm were examined per sample observed. Referring to the results of the evaluation of the heat resistance shown in Table 2, those in which a projection (hillock) having a diameter of 0.1 μm or more was found on the surface observed or in which 4 or more dimples of dented portions (diameter: 0.3 μm to 0.5 μm) were found on the surface observed were evaluated as x, those with less than 4 dimples were evaluated as Δ, and those without any potential defects were evaluated as ◯.

The results obtained in the evaluation methods described above are shown in Table 1.

TABLE 1

| | Ni | B | Total | Specific resistance | Hardness | Corrosion resistance | Bond resistance | 300° C. |
|---|---|---|---|---|---|---|---|---|
| No. | (at %) | (at %) | (at %) | (μΩ cm) | Hv | (Å) | (Ω/□10 μm) | Heat resistance |
| 1 | 0.2 | 0.1 | 0.3 | 3.20 | 24.8 | 141.7 | 214.6 | x |
| 2 | 0.2 | 0.3 | 0.5 | 3.25 | 28.2 | 114.8 | 164.2 | Δ |
| 3 | 0.3 | 0 | 0.3 | 3.14 | 24.1 | 175.2 | 359.0 | x |
| 4 | 0.3 | 0.05 | 0.35 | 3.16 | 25.2 | 164.8 | 196.3 | Δ |
| 5 | 0.3 | 0.1 | 0.4 | 3.24 | 26.4 | 153.7 | 186.4 | ∘ |
| 6 | 0.3 | 0.5 | 0.8 | 3.28 | 30.0 | 109.0 | 141.8 | ∘ |
| 7 | 0.3 | 0.8 | 1.0 | 3.75 | 36.8 | 106.5 | 135.1 | ∘ |
| 8 | 0.3 | 1.0 | 1.3 | 4.08 | 40.7 | 105.2 | 132.5 | ∘ |
| 9 | 0.4 | 0.05 | 0.45 | 3.21 | 31.7 | 189.9 | 160.3 | ∘ |
| 10 | 0.4 | 0.3 | 0.7 | 3.29 | 36.5 | 152.9 | 104.7 | ∘ |
| 11 | 0.5 | 0.05 | 0.55 | 3.24 | 32.7 | 237.9 | 145.6 | Δ |
| 12 | 0.5 | 0.1 | 0.6 | 3.32 | 35.1 | 214.3 | 115.1 | ∘ |
| 13 | 0.5 | 0.15 | 0.65 | 3.32 | 35.6 | 195.3 | 61.5 | ∘ |
| 14 | 0.5 | 0.2 | 0.7 | 3.33 | 36.9 | 190.4 | 53.3 | ∘ |
| 15 | 0.5 | 0.4 | 0.9 | 3.34 | 37.8 | 185.8 | 51.8 | ∘ |
| 16 | 0.5 | 0.6 | 1.1 | 3.65 | 39.3 | 103.9 | 56.8 | ∘ |
| 17 | 0.5 | 0.8 | 1.3 | 3.87 | 42.8 | 103.5 | 52.3 | ∘ |
| 18 | 0.6 | 0.3 | 0.9 | 3.35 | 37.7 | 245.7 | 46.8 | ∘ |
| 19 | 0.6 | 0.4 | 1.0 | 3.36 | 38.0 | 197.3 | 39.9 | ∘ |
| 20 | 0.7 | 0.05 | 0.75 | 3.26 | 34.5 | 332.4 | 112.6 | Δ |
| 21 | 0.7 | 0.1 | 0.8 | 3.34 | 37.6 | 326.5 | 85.6 | ∘ |
| 22 | 0.7 | 0.5 | 1.2 | 3.38 | 38.4 | 283.1 | 37.5 | ∘ |
| 23 | 0.7 | 0.8 | 1.5 | 3.88 | 44.6 | 135.2 | 32.1 | ∘ |
| 24 | 0.8 | 0.3 | 1.1 | 3.40 | 39.8 | 315.6 | 37.4 | ∘ |
| 25 | 1.0 | 0.1 | 1.1 | 3.42 | 39.8 | 359.8 | 57.6 | ∘ |
| 26 | 1.0 | 0.3 | 1.3 | 3.46 | 41.8 | 342.9 | 26.6 | ∘ |
| 27 | 1.0 | 0.5 | 1.5 | 3.48 | 42.3 | 352.3 | 28.6 | ∘ |

The results in Table 1 have revealed that when the total content of Ni and B is less than 0.35 at %, the material has a hardness value of smaller than Hv 25, and when the total content is more than 1.2 at %, the material has a hardness value of greater than Hv 40. Thus, within the composition range in which the total content of Ni and B is 0.35 at % to 1.2 at %, the resulting Al—Ni—B alloy wiring material causes no breakage or cracks in a film even when used in the form of a film on flexible substrates or the like, and has low specific resistance and is heat resistant.

It has also been found that when the Ni content is 0.3 at % or more, the material has a bond resistance value of smaller than 200 Ω/□ 10 μm, and when the Ni content is 0.7 at % or less, the material has a specific resistance value after heat treatment at 300° C. of less than 3.4 μΩcm. Further, it has been shown that when the B content is 0.5 at % or less, the material has a specific resistance value after heat treatment at 300° C. of less than 3.4 μΩcm. It seems to be desirable that the amount of dissolution of film (decrease in the thickness of the film) by a TMAH developer generally used for liquid crystal panels and organic EL after the TMAH development step be within 10% relative to the initial film thickness. It is assumed that the material of the present invention preferably has a composition which provides such corrosion resistance.

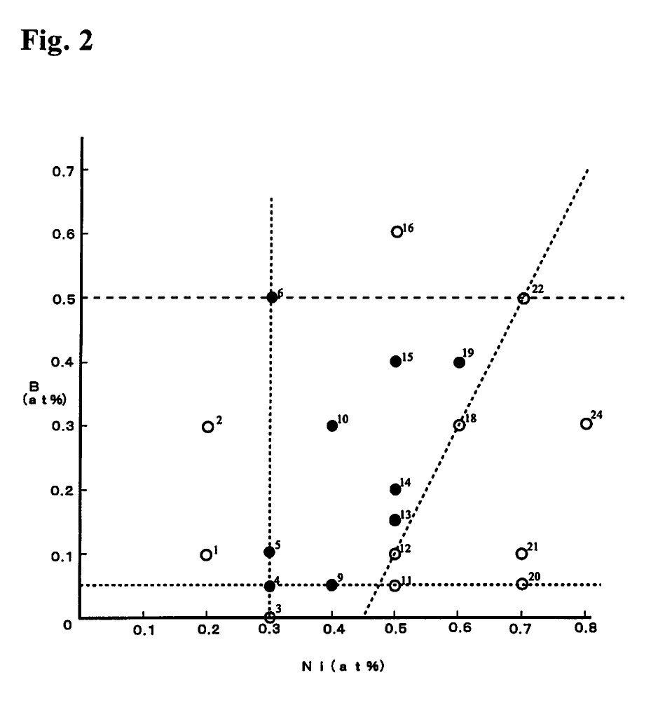

Furthermore, the data of samples in which Ni≦0.8 at % and B≦0.7 at % in Table 1 was studied. A graph plotted with the data in the range of Ni≦0.8 at % and B≦0.7 at % is shown in FIG. 2. The numbers shown in the upper right of the respective plots in the graph of FIG. 2 correspond to the sample numbers in Table 1. In the graph of FIG. 2, the plots show the data of materials having a specific resistance value of 3.6 μΩcm or less, a hardness of 40 Hv or less, a corrosion resistance of 200 Å or less, a bond resistance value of 200Ω/□ 10 μm or less, and the 300° C. heat resistance evaluated as ◯. On the other hand, the plots ◯ show the data of materials in which any of the aforementioned items was not satisfied. The results in FIG. 2 have shown that when the content of nickel is represented by nickel atomic percent X at % and the content of boron is represented by boron atomic percent Y at %, particularly preferred ranges of the composition are in the domain bounded by the formulas of 0.3≦X, 0.05≦Y≦0.5, Y>2X−0.9. The domain bounded by the formulas is in a range shown by dotted lines in FIG. 2. For the formula Y>2X−0.9, a formula which satisfies the above properties more reliably is the formula of Y≧2X−0.85 which includes the composition of the sample No. 13.

### INDUSTRIAL APPLICABILITY

The Al—Ni alloy wiring electrode material of the present invention is excellent in corrosion resistance against developers, the material itself has flexibility and can be directly bonded to a transparent electrode layer of ITO or the like, and therefore is suitable as a material constituting an organic EL display. The Al—Ni alloy wiring electrode material of the present invention is also suitable for a lead wiring material and a reflective film material in an organic EL display.

1. An Al—Ni alloy wiring electrode material comprising aluminum, nickel and boron, wherein the material comprises 0.3 at % to 0.7 at % of nickel and 0.05 at % to 0.5 at % of boron, and contains a total of 0.35 at % to 1.2 at % of nickel and boron with the balance being aluminum, and wherein when a content of nickel is represented by nickel atomic percent X at % and a content of boron is represented by boron atomic percent Y at %, the content thereof is in the range of a domain satisfying the formulas:
0.3<X
0.05<Y<0.5 and
Y>2X−0.9.

2. (canceled)

3. (canceled)

4. The Al—Ni alloy wiring electrode material according to claim 1, which is for organic EL.

5. A sputtering target for forming a wiring electrode film composed of the Al—Ni alloy wiring electrode material, the electrode material defined in claim 1, wherein the sputtering target comprises 0.3 at % to 0.7 at % of nickel and 0.05 at % to 0.5 at % of boron, and contains a total of 0.35 at % to 1.2 at % of nickel and boron with the balance being aluminum, and wherein when a content of nickel is represented by nickel atomic percent X at % and a content of boron is represented by boron atomic percent Y at %, the content thereof is in the range of a domain satisfying the formulas:
0.3<X
0.05<Y<0.5 and
Y>2X−0.9.

6. (canceled)

7. (canceled)
